(19) United States
(12) Patent Application Publication
(10) Pub. No.: US 2017/0162520 A1
(43) Pub. Date: Jun. 8, 2017

(54) LEAD FRAME, ELECTRONIC COMPONENT DEVICE, AND METHODS OF MANUFACTURING THEM

(71) Applicant: SHINKO ELECTRIC INDUSTRIES CO., LTD., Nagano-shi (JP)

(72) Inventors: Kentaro Kaneko, Nagano-shi (JP); Yoji Asahi, Nagano-shi (JP); Tsuyoshi Kobayashi, Nagano-shi (JP); Koji Watanabe, Nagano-shi (JP); Kenichi Komatsu, Nagano-shi (JP); Toru Maruyama, Nagano-shi (JP); Konosuke Kobayashi, Nagano-shi (JP); Koji Ato, Nagano-shi (JP)

(21) Appl. No.: 15/365,281

(22) Filed: Nov. 30, 2016

(30) Foreign Application Priority Data
Dec. 2, 2015 (JP) 2015-235825

(51) Int. Cl. H01L 23/00; H01L 21/56; H01L 21/48; H01L 23/495; H01L 23/31

(52) U.S. Cl. CPC H01L 23/562; H01L 23/49503; H01L 23/49548; H01L 23/4952; H01L 23/3114; H01L 21/4828; H01L 21/4825; H01L 21/565

(57) ABSTRACT

A lead frame includes a terminal part having a first side surface formed in a concave curve shape on a lower side from an upper end of the terminal part, and a second side surface formed in a concave curve shape on a lower side from a lower end of the first side surface. The concave curve shape of each of the first and second side surfaces has a depth in a surface direction of the terminal part. A boundary part of the first side surface and the second side surface becomes a protrusion protruding outward. The depth of the concave curve shape of the second side surface is larger than that of the first side surface. A distance between an upper end and a lower end of the second side surface is longer than a distance between an upper end and the lower end of the first side surface.

### CROSS-REFERENCE TO RELATED APPLICATION

The present application claims priority from Japanese Patent Application No. 2015-235825 filed on Dec. 2, 2015, the entire content of which is incorporated herein by reference.

### BACKGROUND

Technical Field

The present invention relates to a lead frame, an electronic component device, and methods of manufacturing them.

Related Art

In the related art, there are lead frames for mounting electronic components such as semiconductor chips. On such a lead frame, a semiconductor chip mounted on a die pad is connected to the surrounding leads by wires, and the semiconductor chip and the wires are sealed with a sealing resin.

Patent Document 1: Japanese Patent Laid-Open Publication No. 2012-69886

As will be described with a preliminary technology, in order to prevent the lead frame from slipping out of the sealing resin, protrusions are formed at the upper ends of the side surfaces of terminal parts of the lead frame. However, the protrusions which are formed by wet etching using an etching inhibitor are very thin and acuate.

For this reason, there is a problem that, if vertical stress is applied to the lead frame, since the protrusions of the terminal parts are chipped, and thus do not function as anchors, sufficient reliability is not achieved.

Also, when a semiconductor chip is connected to the terminal parts by wire bonding, the protrusions may be chipped.

### SUMMARY

Exemplary embodiments of the invention provide a lead frame and an electronic component device capable of obtaining sufficient adhesion between terminal parts and sealing resin, and methods of manufacturing them.

A lead frame according to an exemplary embodiment of the invention comprises:

a terminal part formed of a metal plate; and

a die pad part formed of the metal plate,

wherein each of the terminal part and the die pad part comprises
a first side surface formed in a concave curve shape on a lower side from an upper end of the corresponding terminal part or the die pad part, the concave curve shape having a depth in a surface direction of the corresponding terminal part or the die pad part, and
a second side surface formed in a concave curve shape on a lower side from a lower end of the first side surface, the concave curve shape having a depth in the surface direction of the corresponding terminal part or the die pad part, and

wherein in said each of the terminal part and the die pad part,

a boundary part of the first side surface and the second side surface becomes a protrusion protruding outward,

the depth of the concave curve shape of the second side surface is larger than the depth of the concave curve shape of the first side surface,

a distance between an upper end and a lower end of the second side surface is longer than a distance between an upper end and a lower end of the first side surface, and

a surface of the die pad part positioned on a side where the first side surface is formed is an electronic-component mounting surface.

An electronic component device according to an exemplary embodiment of the invention comprises:

a lead frame which includes
a terminal part formed of a metal plate, and
a die pad part formed of the metal plate, and
in which each of the terminal part and the die pad part has
   a first side surface formed in a concave curve shape on a lower side from an upper end of the corresponding terminal part or the die pad part, the concave curve shape having a depth in a surface direction of the corresponding terminal part or the die pad part, and
   a second side surface formed in a concave curve shape on a lower side from a lower end of the first side surface, the concave curve shape having a depth in the surface direction of the corresponding terminal part or the die pad part, and
in said each of the terminal part and the die pad part,
   a boundary part of the first side surface and the second side surface becomes a protrusion protruding outward,
   the depth of the concave curve shape of the second side surface is larger than the depth of the concave curve shape of the first side surface,
   a distance between an upper end and a lower end of the second side surface is longer than a distance between an upper end and a lower end of the first side surface, and
   a surface of the die pad part positioned on a side where the first side surface is formed is an electronic-component mounting surface;

an electronic component mounted on the electronic-component mounting surface of the lead frame and electrically connected to the terminal part; and

a sealing resin formed so as to cover the electronic component and the first side surfaces and the second side surfaces of the terminal part and the die pad part.

A method of manufacturing a lead frame, according to an exemplary embodiment of the invention, comprises:

a step of forming a first resist layer having an opening on an upper surface of a metal plate;

a first etching step of performing wet etching on the metal plate through the opening of the first resist layer to the middle of the thickness of the metal plate, thereby forming a first recess;

a step of removing the first resist layer;

a step of forming a second resist layer on the upper surface of the metal plate such that the second resist layer has an opening on the first recess while covering a circumferential edge part of an inner wall surface of the first recess; and

a second etching step of performing etching on the metal plate from a bottom surface of the first recess through the opening of the second resist layer,

wherein, by performing the second etching step,
a first side surface obtained from the circumferential edge part of the inner wall surface of the first recess and formed in a concave curve shape, the concave curve shape having a depth in a surface direction of the metal plate, and a second side surface bordering a lower end of the first side surface and formed in a concave curve shape, the concave curve shape having a depth in the surface direction of the metal plate, are formed,
a boundary part of the first side surface and the second side surface becomes a protrusion protruding outward,
the depth of the concave curve shape of the second side surface is formed so as to be larger than the depth of the concave curve shape of the first side surface, and
a distance between an upper end and a lower end of the second side surface is set to be longer than a distance between an upper end and a lower end of the first side surface.

According to the following disclosure, each of terminal part and a die pad part of a lead frame has a first side surface formed in a concave curve shape on the lower side from its upper end, and a second side surface formed in a concave curve shape on the lower side from the lower end of the first side surface. Further, the boundary part between the first side surface and the second side surface becomes a protrusion protruding outward.

Since the first side surface including the protrusion has a required distance between the upper end and the lower end, the first side surface is thick to some extent. Therefore, even if vertical stress is applied to the lead frame, the protrusions are not clipped, and sufficiently function as anchors. Therefore, sufficient reliability is achieved.

### BRIEF DESCRIPTION OF THE DRAWINGS

FIGS. 1A to 1D are cross-sectional views for explaining an issue in a lead frame according to a preliminary technology.

FIGS. 2A to 2C are other cross-sectional views for explaining the issue in the lead frame according to the preliminary technology.

FIGS. 3A and 3B are cross-sectional views illustrating a first portion of a method of manufacturing a lead frame of a first embodiment.

FIG. 4A to 4D are cross-sectional views illustrating a second portion of the method of manufacturing the lead frame of the first embodiment.

FIGS. 5A and 5D are cross-sectional views illustrating a third portion of the method of manufacturing the lead frame of the first embodiment.

FIG. 6 is a cross-sectional view illustrating a fourth portion of the method of manufacturing the lead frame of the first embodiment.

FIG. 7 is a cross-sectional view illustrating a fifth portion of the method of manufacturing the lead frame of the first embodiment.

FIGS. 8A and 8B are cross-sectional views illustrating a sixth portion of the method of manufacturing the lead frame of the first embodiment.

FIGS. 9A and 9B are cross-sectional views illustrating a seventh portion of the method of manufacturing the lead frame of the first embodiment.

FIGS. 10A and 10B are cross-sectional views illustrating the lead frame and an electronic component device of the first embodiment.

FIGS. 11A and 11B are cross-sectional views illustrating another lead frame of the first embodiment.

FIGS. 12A to 12C are cross-sectional views illustrating a method of manufacturing a lead frame of a modification of the first embodiment.

FIGS. 13A and 13B are cross-sectional views illustrating a first portion illustrating a method of manufacturing a lead frame of a second embodiment.

FIGS. 14A to 14C are cross-sectional views illustrating a second portion of the method of manufacturing the lead frame of the second embodiment.

FIGS. 15A and 15B are cross-sectional views illustrating a third portion of the method of manufacturing the lead frame of the second embodiment.

FIGS. 16A and 16B are cross-sectional views illustrating the lead frame of the second embodiment.

FIG. 17 is a cross-sectional view illustrating an electronic component device of the second embodiment.

FIGS. 18A to 18C are cross-sectional views illustrating a method of manufacturing a lead frame according to a third embodiment.

FIGS. 19A and 19B are cross-sectional views illustrating the lead frame of the third embodiment.

FIG. 20 is a cross-sectional view illustrating an electronic component device of the third embodiment.

FIGS. 21A to 21C are cross-sectional views illustrating a method of manufacturing a lead frame according to a fourth embodiment.

FIGS. 22A and 22B are cross-sectional views illustrating the lead frame of the fourth embodiment.

FIG. 23 is a cross-sectional view illustrating an electronic component device of the fourth embodiment.

FIGS. 24A to 24C are cross-sectional views illustrating a method of manufacturing a lead frame according to a fifth embodiment.

FIGS. 25A and 25B are cross-sectional views illustrating the lead frame of the fifth embodiment.

FIG. 26 is a cross-sectional view illustrating an electronic component device of the fifth embodiment.

### DETAILED DESCRIPTION

Hereinafter, embodiments will be described with reference to the accompanying drawings.

Prior to a description of embodiments, a preliminary technology underlying them will be described.

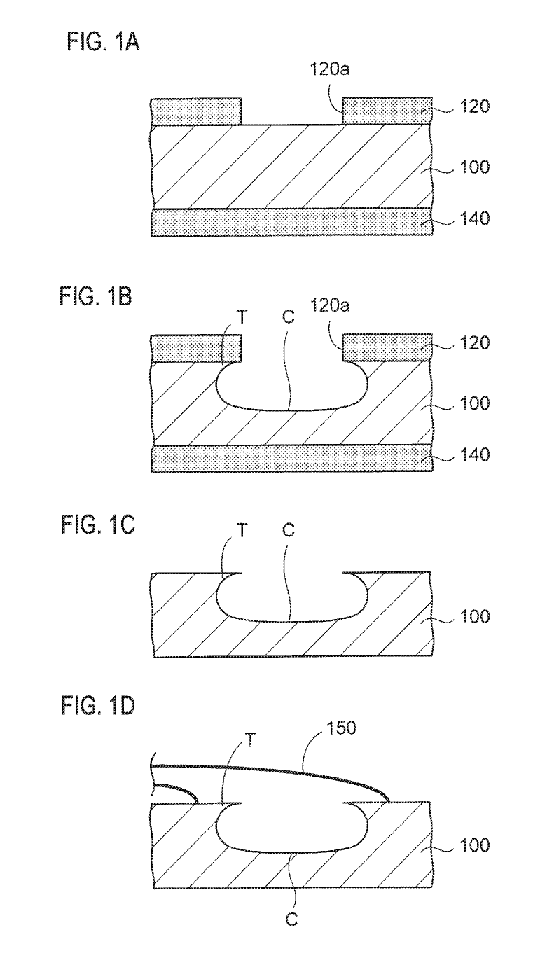

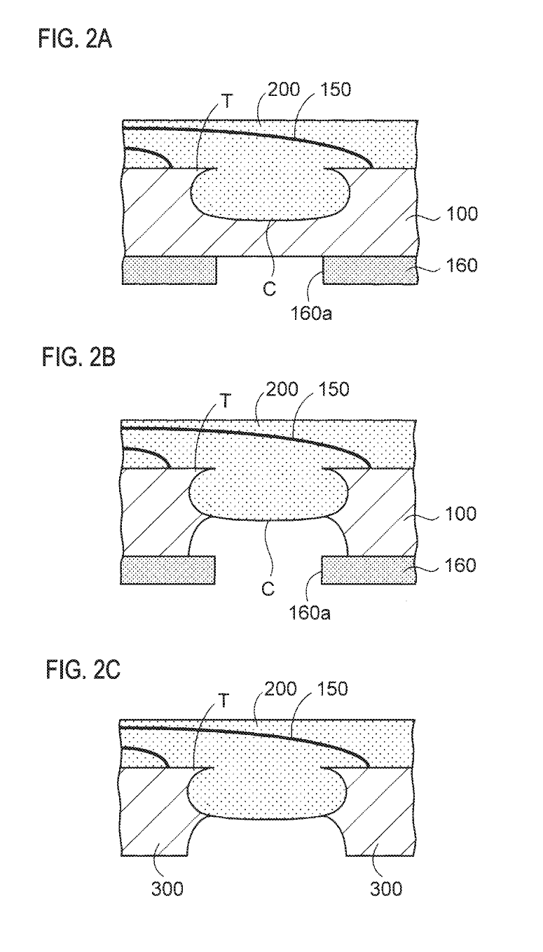

FIGS. 1A to 2C are views for explaining an issue in lead frames according to the preliminary technology. A description of the preliminary technology includes the contents of unknown novel technologies as the contents of personal examination of the inventors.

In a method of manufacturing a lead frame according to the preliminary technology, as shown in FIG. 1A, first, a thin copper plate 100 made of rolled copper foil or the like is prepared. Subsequently, on the top surface of the copper plate 100, a first resist layer 120 is formed so as to have openings 120a by patterning. Further, over the entire bottom surface of the copper plate 100, a second resist layer 140 is formed to protect the bottom surface.

Subsequently, wet etching is performed on the copper plate 100 through the openings 120a of the first resist layer 120 to the middle of the thickness of the copper plate, whereby recesses C are formed as shown in FIG. 1B. The wet etching is performed by spray etching using a wet etching solution usable for copper and containing an etching inhibitor.

In this case, the etching inhibitor adheres to etching surfaces positioned immediately below the side surfaces of the openings 120a of the first resist layer 120, and etching in a horizontal direction is suppressed due to action of the etching inhibitor. Since an amount of etching inhibitor which adheres to the side surfaces decreases as etching progresses, at the middle parts of the side surfaces of the recesses C of the copper plate 100, an amount of side etching increases, and the side surfaces are etched in the horizontal direction so that each of the side surfaces has a shape having the depth in the horizontal direction.

As a result, eave-shaped protrusions T are formed at the upper ends of the side surfaces of the recesses C. As will be described below, when an electronic component device is constructed, a sealing resin is filled in the recesses C, and the protrusions T function as anchors to prevent the lead frame from slipping out of the sealing resin.

Thereafter, the first resist layer 120 and the second resist layer 140 are removed as shown in FIG. 1C.

Subsequently, as shown in FIG. 1D, a semiconductor chip (not shown) is mounted on an area of the copper plate 100 to be a die pad part, and the semiconductor chip and parts of the copper plate 100 to be terminal parts are connected by wires 150. In FIG. 1D, some of areas of the copper plate 100 to be the terminal parts are shown.

Thereafter, the semiconductor chip, the wires 150, and the copper plate 100 are sealed with a sealing resin 200, as shown in FIG. 2A. Subsequently, on the bottom surface of the copper plate 100, a third resist layer 160 is formed so as to have openings 160a at areas corresponding to the recesses C.

Next, wet etching is performed on the bottom surface of the copper plate 100 through the openings 160a of the third resist layer 160 until the sealing resin 200 positioned at the bottoms of the recesses C is exposed as shown in FIG. 2B. Thereafter, the third resist layer 160 is removed.

In this way, through-holes are formed in the copper plate 100 in a predetermined pattern as shown in FIG. 2C by performing wet etching from the top surface and the bottom surface. Therefore, a die pad part (not shown) and terminal parts 300 are separately formed. In the above-described way, the semiconductor chip is electrically connected to the lead frame, whereby an electronic component device is constructed.

As described above, the protrusions T of the upper ends of the terminal parts 300 function as anchors to prevent the lead frame from slipping out of the sealing resin 200. However, the protrusions T which are formed by action of the etching inhibitor are very thin and acuate. For this reason, if vertical stress is applied to the electronic component device, the protrusions T are chipped and do not function as anchors. Therefore, there is a problem that sufficient reliability of the electronic component device is not achieved.

Also, wet etching using the etching inhibitor as an additive has a problem that, since the dimensions of the recesses C easily vary due to some causes such as the amount of added etching inhibitor and the pressure and temperature of the etching solution when they are formed, the dimensions of the surfaces of the terminal parts 300 are not stable.

The above-described problems can be solved by lead frames of embodiments to be described below.

### First Embodiment

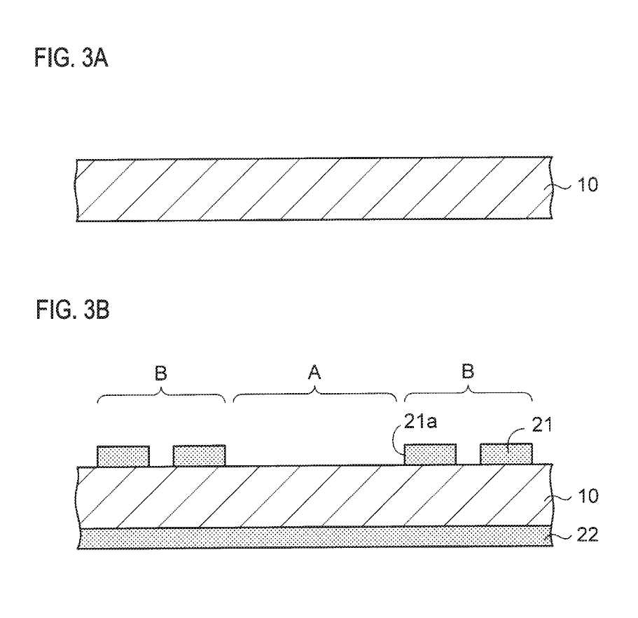

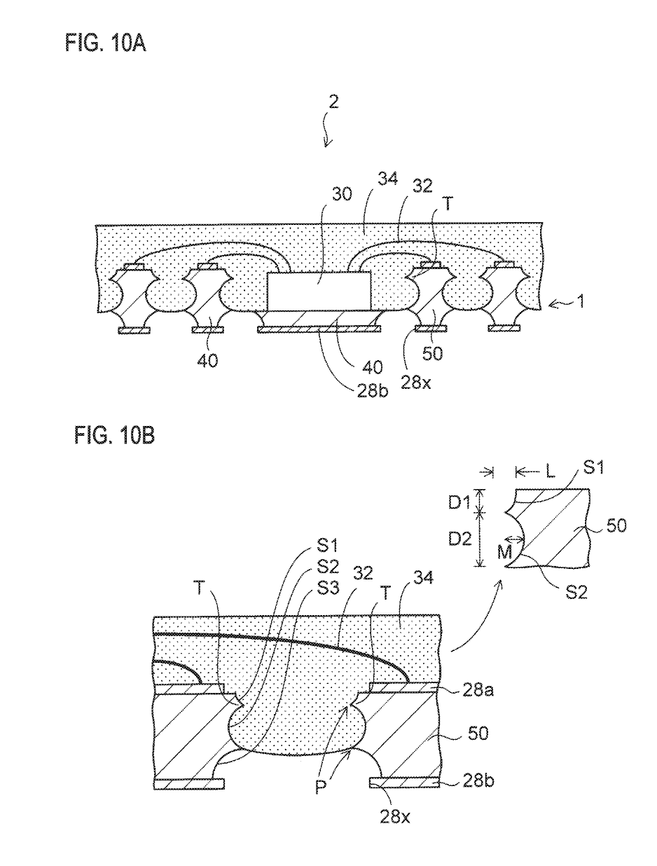

FIGS. 3A to 9B are views for explaining a method of manufacturing a lead frame of a first embodiment, and FIGS. 10A and 10B are views illustrating the lead frame and an electronic component device of the first embodiment.

Hereinafter, with a description of methods of manufacturing the lead frame and the electronic component device, the structures of the lead frame and the electronic component device will be described.

In the method of manufacturing the lead frame of the first embodiment, first, a copper plate 10 as shown in FIG. 3A is prepared. As the copper plate 10, rolled copper foil having a thickness between 75 μm and 200 μm can be used. The copper plate 10 is a preferred example of a metal plate, and various metal plates usable as lead frames can be used.

Next, on the top surface of the copper plate 10, a first resist layer 21 is formed so as to have openings 21a as shown in FIG. 3B by patterning. Also, a second resist layer 22 is formed over the entire bottom surface of the copper plate 10 so as to protect the bottom surface.

As the first and second resist layers 21 and 22, a liquid resist, a dry film resist, or an electrodeposition resist can be used. The openings 21a of the first resist layer 21 are formed by performing exposure and development on the basis of photolithography.

Instead of the first and second resist layers 21 and 22, gold-plated layers can be used as masks.

In the copper plate 10, there is a die pad area “A” defined for disposing a die pad part for mounting a semiconductor chip, and terminal areas “B” defined for disposing terminal parts.

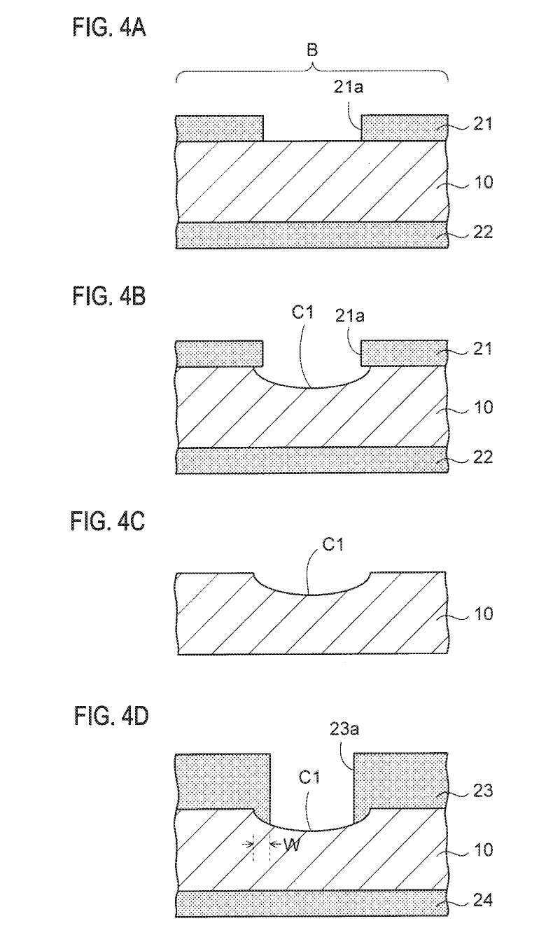

The following description will be made with reference to some drawings illustrating a part of the terminal areas “B” of the copper plate 10 of FIG. 3B. FIG. 4A is an enlarged view of a part of the terminal areas “B” of the copper plate 10 of FIG. 3B.

Next, wet etching is performed on the top surface of the copper plate 10 through the openings 21a of the first resist layer 21, to the middle of the thickness of the copper plate, whereby first recesses C1 are formed as shown in FIG. 4B.

In wet etching of the present embodiment, an etching solution which does not contain any etching inhibitor is used. As etching equipment, spray wet etching equipment is suitably used; however, other etching equipments such as a dip type and a spinner type may also be used.

As the etching solution for the copper plate 10, a ferric chloride solution, a cupric chloride solution, an alkaline etching solution, or the like can be used. As an alkaline etching solution, for example, a copper ammonium chloride solution can be used.

Since an etching solution which does not contain any etching inhibitor is used in wet etching, the copper plate 10 is etched from the insides of the openings 21a of the first resist layer 21 by completely isotropic etching. In isotropic etching, the amount of etching in the thickness direction is the same as that in the horizontal direction.

For this reason, the depth in the horizontal direction from the lower end of the side surface of each opening 21a of the first resist layer 21 has the same dimension as the depth in the thickness direction from the lower end of the corresponding side surface of each opening 21a is obtained, and thus the inner surface of each first recess C1 is formed in a concave curve shape. The depth in the thickness direction of the first recesses C1 is set between 10 μm and 50 μm. In the following description, “the depth in the thickness direction” will be simply referred as “the depth”.

As described above, in the present embodiment, since any etching inhibitor is not used unlike the preliminary technology, at this stage, any protrusions are not formed at the upper ends of the first recesses C1.

Thereafter, the first and second resist layers 21 and 22 are removed as shown in FIG. 4C. In this process of removing the resist layers, the resist layers are peeled off by a resist peeling liquid. As the resist peeling liquid, caustic soda or an amine-based organic solvent can be used.

Next, a third resist layer 23 is formed on the top surface of the copper plate 10 of FIG. 4C, so as to have openings 23a on the first recesses C1 as shown in FIG. 4D. The openings 23a of the third resist layer 23 are disposed on the central parts of the first recesses C1, with the circumferential edge parts of the inner wall surfaces of the first recesses C1 covered by the third resist layer 23.

An amount by which the third resist layer 23 covers each first recess C1 from the edge of the corresponding recess is set between 10 μm and 50 μm.

Since the third resist layer 23 is formed on the uneven top surface of the copper plate 10 having the first recesses C1, it is formed by laminating a dry film resist thicker than the first resist layer 21 with a vacuum laminator. In this way, the third resist layer 23 can be formed even on the first recesses C1 without any gap, and the pattern of the third resist layer 23 can be formed with reliability.

Also, similarly, a fourth resist layer 24 is formed over the entire bottom surface of the copper plate 10 as shown in FIG. 4D, so as to protect the bottom surface.

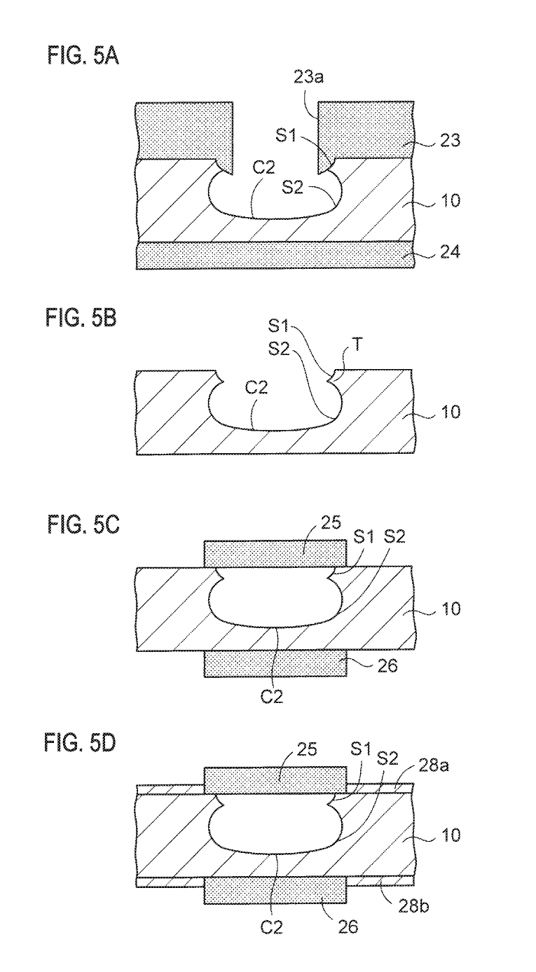

Next, wet etching is performed on the copper plate 10 through the openings 23a of the third resist layer 23 to the middle of the thickness of the copper plate from the bottom surfaces of the first recesses C1, as shown in FIG. 5A. Even at this time, a wet etching solution which does not contain any etching inhibitor is used. Therefore, the copper plate 10 is etched from the insides of the openings 23a of the third resist layer 23 by completely isotropic etching.

As a result, the first recesses C1 become deeper with first side surfaces S1 remaining at the circumferential edge parts of the inner wall surfaces of the first recesses C1, whereby second recesses C2 are formed. Each second recess C2 is formed so as to have the first side surface S1 of a corresponding first recess C1 and a second side surface S2 bordering the first side surface. Thereafter, the third resist layer 23 and the fourth resist layer 24 are removed as shown in FIG. 5B.

The depth of the second recesses C2 can be set to, for example, about two thirds of the overall thickness of the copper plate 10.

The copper plate 10 is etched from the lower ends of a corresponding first side surfaces S1 remaining due to covering of the third resist layer 23, whereby the second side surfaces S2 of the second recesses C2 are formed in a concave curve shape having the depth in the horizontal direction of the copper plate 10 as shown in FIG. 5B.

Therefore, the boundary parts between the first side surfaces S1 and the second side surfaces S2 becomes protrusions T. The first side surfaces including the protrusions T as shown in FIG. 5B function as anchors to prevent a lead frame from slipping out of a sealing resin when an electronic component device is constructed, as described with respect to the preliminary technology.

The first side surfaces including the protrusions T as shown in FIG. 5B are formed so as to be thick to some extent such that they have a required distance between the upper ends and the lower ends. Therefore, even if vertical stress is applied to the electronic component device, the protrusions T are not clipped. Therefore, sufficient reliability of the electronic component device is achieved.

Next, a fifth resist layer 25 is formed on the top surface of the copper plate 10 so as to cover the second recesses C2 as shown in FIG. 5C by patterning. Further, a sixth resist layer 26 is formed on the bottom surface of the copper plate 10 so as to correspond to the second recesses C2 by patterning.

Subsequently, metal-plated layers 28a and 28b are formed on areas of the top surface and bottom surface of the copper plate 10 exposed from the fifth and sixth resist layers 25 and 26, respectively, as shown in FIG. 5D, by electrolytic plating using the copper plate 10 as a power supply passage for plating.

The metal-plated layers 28a and 28b each are formed of a single metal layer or a plurality of metal layers made of gold (Au), palladium (Pd), nickel (Ni), silver (Ag), tin (Sn), zinc (Zn), etc.

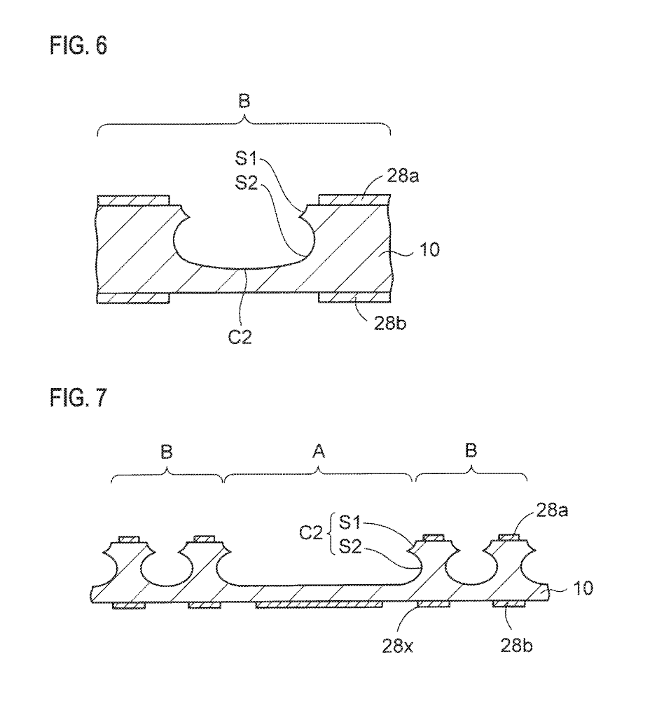

Thereafter, the fourth and fifth resist layers 24 and 25 are removed as shown in FIG. 6. The shape of the entire copper plate 10 at this stage is shown in FIG. 7. As shown in FIG. 7, even in the die pad area “A” of the copper plate 10, a second recess C2 is formed in the same shape. The bottom surface of the second recess C2 formed in the die pad area “A” becomes an electronic-component mounting surface, and a semiconductor chip is mounted thereon.

In this way, patterning is performed to the middle of the thickness, whereby a lead frame having areas to be terminal parts and an area to be a die pad part is obtained.

The pattern of the metal-plated layer 28b is disposed on the bottom surface of the copper plate 10 so as to correspond to the die pad area “A” and the parts of the terminal areas “B” to be the terminal parts. Then, wet etching is performed on the bottom surface of the copper plate 10 through openings 28x of the metal-plated layer 28b, whereby the die pad part and the individual terminal parts are separately obtained.

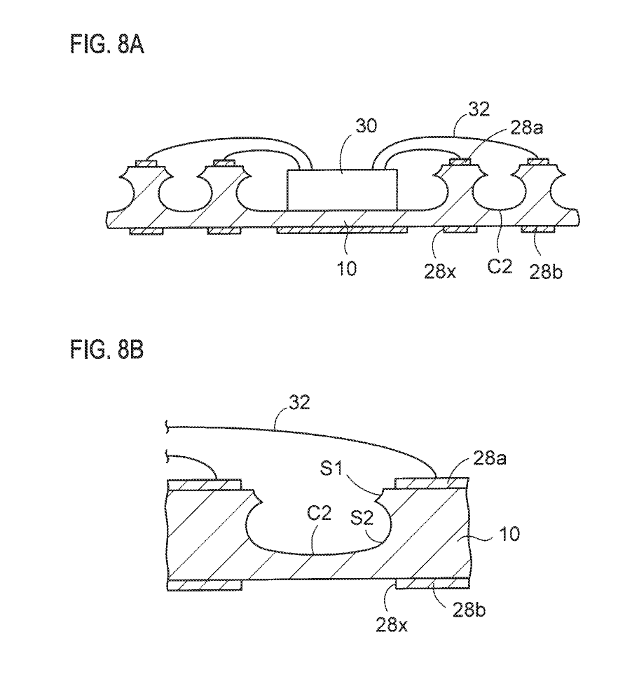

Thereafter, a semiconductor chip 30 is mounted on the bottom surface of the second recess C2 of the die pad area “A” of the copper plate 10 of FIG. 7, as shown in FIGS. 8A and 8B. Further, connection parts of the semiconductor chip 30 are connected to parts of the metal-plated layer 28a positioned in the terminal areas “B” of the copper plate 10 by wires 32. As the wires 32, gold wires, copper wires, and the like can be used.

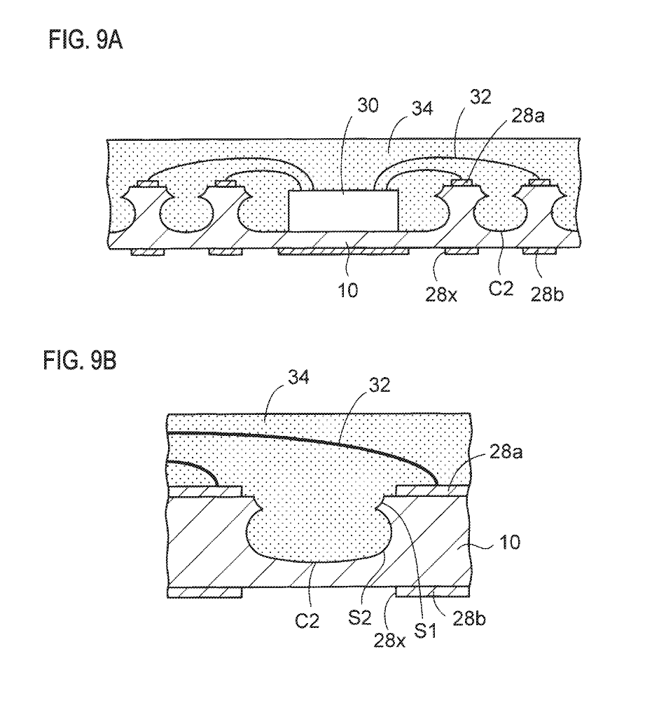

Subsequently, a sealing resin 34 is formed so as to seal the semiconductor chip 30, the wires 32, and the copper plate 10 as shown in FIGS. 9A and 9B. At this time, the second recesses C2 of the copper plate 10 are filled with the sealing resin 34.

In this way, one surface side of the copper plate 10, the first side surfaces S1 and the second side surfaces S2 positioned in the areas to be the terminal parts and the area to be the die pad part, and the semiconductor chip 30 are sealed with the sealing resin 34.

Further, wet etching is performed on the copper plate 10 from the bottom surface side through the openings 28x of the metal-plated layer 28b positioned on the lower side of the copper plate 10, as shown in FIGS. 10A and 10B, until the sealing resin 34 positioned at the bottoms of the second recesses C2 are exposed.

In this way, through-holes are formed in the copper plate 10 so as to connect the top surface and the bottom surface, whereby the copper plate 10 is patterned. Further, third side surfaces S3 are formed below the lower ends of the second side surfaces S2. The third side surfaces S3 are formed so as to be exposed from the sealing resin 34 and protrude downward from the sealing resin 34.

An example of one surface side of the metal plate is the top surface side of the copper plate 10, and an example of the other surface side of the metal plate is the bottom surface side of the copper plate 10.

As a result, the die pad area “A” and the terminal areas “B” of the copper plate 10 are separated, and the pattern of the copper plate 10 having the semiconductor chip 30 mounted thereon becomes a die pad part 40. Also, the terminal areas “B” of the copper plate 10 are patterned, whereby terminal parts 50 separated from each other are obtained.

In the above-described way, while a lead frame 1 of the first embodiment is obtained, an electronic component device 2 having the semiconductor chip 30 mounted on the lead frame 1 is obtained. The semiconductor chip 30 is an example of an electronic component, and an electronic component device may be constructed by mounting various electronic components on the lead frame.

As shown in FIG. 10A, the lead frame 1 of the first embodiment has the die pad part 40, and the terminal parts 50 disposed around the die pad part. The die pad part 40 and the terminal parts 50 are separated, thereby being electrically insulated. Below the die pad part 40, there is a part of the metal-plated layer 28b.

Also, as shown in a partially enlarged sectional view of FIG. 10B, there are parts of the metal-plated layer 28a on the top surfaces of the terminal parts 50, and there are parts of the metal-plated layer 28b on the bottom surfaces of the terminal parts. As described above, the die pad part 40 and the terminal parts 50 are formed by patterning the copper plate 10. The copper plate 10 is an example of the metal plate, and the die pad part 40 and the terminal parts 50 can be made of various metal plates.

The thickness of the die pad part 40 is set to be smaller than the thickness of the terminal parts 50. The height position of the die pad part 40 is lower than the height position of the top surfaces of the terminal parts 50. Further, the top surface of the die pad part 40 becomes an electronic component mounting surface, and the semiconductor chip 30 is mounted on the electronic-component mounting surface. The die pad part 40 is formed so as to have the same side surface as the third side surfaces S3 of the terminal parts 50.

The connection parts of the semiconductor chip 30 and parts of the metal-plated layer 28a formed on the terminal parts 50 are connected by the wires 32. In this way, the semiconductor chip 30 is electrically connected to the terminal parts 50 of the lead frame 1. Also, the semiconductor chip 30, the die pad part 40, the terminal parts 50, and the wires 32 are sealed by the sealing resin 34.

Also, as shown in the partially enlarged sectional view of FIG. 10B, each terminal part 50 has a first side surface S1, a second side surface S2, and a third side surface S3 in order from the top.

The first side surfaces S1 are formed in a concave curve shape on the lower sides from the upper ends of the terminal parts 50. Also, the second side surfaces S2 are formed in a concave curve shape on the lower sides from the lower ends of the first side surfaces S1, such that the upper ends of the second side surfaces S2 border the lower ends of the first side surfaces S1. The side surface of each concave curve shape is formed in an arc shape forming a part of a circle as seen in a cross-sectional view.

Also, the second side surfaces S2 are formed by etching the terminal parts 50 from the lower ends of the first side surfaces S1 so that the second side surfaces S2 have the shape having the depth in the horizontal direction.

As a result, the boundary parts between the first side surfaces S1 and the second side surfaces S2 become the protrusions T protruding outward.

As a preferred example, a distance D1 between the upper ends and lower ends of the first side surfaces S1 is within a range between 1 μm and 20 μm. Also, a length L1 in the horizontal direction between the upper ends and lower ends of the first side surfaces S1 is within a range between 5 μm and 30 μm. Also, the depth M in the horizontal direction from the lower ends of the first side surface S1 of the second side surfaces S2 is within a range between 5 μm and 30 μm.

Also, a distance D2 between the upper ends and lower ends of the second side surfaces S2 is set to be longer than the distance D1 between the upper ends and lower ends of the first side surfaces S1.

The second side surfaces S2 are positioned on the inner sides of the terminal parts 50 from the positions of the first side surfaces S1. In other words, the depth in the horizontal direction (which is the surface direction of the copper plate 10) of each of the second side surfaces S2 is larger than the depth in the horizontal direction of the each of the first side surfaces S1.

Further, the third side surfaces S3 are formed in a concave curve shape on the lower sides from the lower ends of the second side surfaces S2 such that the upper ends of the third side surfaces S3 border the lower ends of the second side surfaces S2. The lower ends of the third side surfaces S3 border the lower surfaces of the terminal parts 50. The third side surfaces S3 are exposed from the sealing resin 34, and protrude downward from the lower end of the sealing resin 34.

In the first embodiment, since the side surface of each terminal part 50 has three side surfaces, that is, first to third side surfaces S1 to S3 having the concave curve shapes and connected in order, it has two side surface protrusions P protruding outward from the side surface at the boundaries of the first to third side surfaces.

The sealing resin 34 is formed so as to seal the first side surfaces S1 and the second side surfaces S2 of the terminal parts 50, and the third side surfaces S3 are exposed without being sealed by the sealing resin 34.

The protrusions T formed on the upper end sides of the terminal parts 50 function as anchors to prevent the lead frame 1 from slipping out of the sealing resin 34.

In the present embodiment, as described above with reference to FIGS. 4D to 5B, the second recesses C2 are formed in the bottoms of the first recesses C1 with the circumferential edge parts of the inner wall surfaces of the first recesses C1 (to be the first side surfaces S1) covered by the third resist layer 23.

Therefore, when the second recesses C2 are formed, the first side surfaces S1 having the necessary distance D1 between the upper ends and the lower ends are surely ensured. Further, since the second recesses C2 are formed by performing etching on the first side surfaces S1, the boundary parts between the first side surfaces S1 and the second side surfaces S2 become the protrusions T protruding outward.

Since the first side surfaces S1 including the protrusions T have the necessary distance D1 between the upper ends and the lower ends, they are thick to some extent. Therefore, even if vertical stress is applied to the electronic component device 2, the protrusions T are not clipped, and sufficiently function as anchors. Therefore, sufficient reliability of the electronic component device is obtained.

Also, the side surface of each terminal part 300 of the preliminary technology has only one side surface protrusion formed at the central part. In contrast with this, in the first embodiment, each terminal part 50 has three side surfaces, that is, first to third side surfaces S1 to S3, and thus has two side surface protrusions P.

For this reason, the cross section shapes of the terminal parts 50 become complicated, and their contact areas with the sealing resin 34 increase. Therefore, the terminal parts 50 have such a structure that it is difficult for them to slip out of the sealing resin 34.

The positions of two side surface protrusions P can be moved in the vertical direction by adjusting the etching depths of the first recesses C1 and the second recesses C2 (FIGS. 4B and 5A).

Also, the surface sizes of the terminal parts 50 are approximately determined on the basis of the sizes of the first recesses C1 of FIG. 4C described above. The etching depth of the first recesses C1 is relatively shallow, specifically, 10 μm to 50 μm, and the first recesses C1 are formed by isotropic wet etching which does not use any etching inhibitor.

Therefore, it is possible to suppress variation in the sizes of the first recesses C1, and thus it is possible to stabilize the surface sizes of the terminal parts 50.

As a result, it becomes easy to derive pattern correction during design of photomasks for forming the terminal parts 50 and the like, and a cost advantage is obtained.

Also, the shape of the protrusions T and the depth M in the horizontal direction of the second side surfaces S2 can be adjusted by adjusting the etching depths of the first recesses C1 and the second recess C2 (FIGS. 4B and 5A) and the amount W of covering of the third resist layer 23 of FIG. 4D.

Also, in the first embodiment, since parts corresponding to the recesses C of FIG. 1C of the preliminary technology are formed by forming the first recesses C1 and the second recesses C2 in two separate steps, respectively, it is possible to reduce the depths in the horizontal direction of the second recesses C2 in the terminal parts 50. As a result, when the semiconductor chip 30 and the terminal parts 50 are connected with the wires 32 by wire bonding, the terminal part 50 are prevented from being damaged.

Also, in the present embodiment, the first side surface S1 of each terminal part 50 has the length L in the horizontal direction between the upper end and the lower end. Therefore, if each terminal part 50 is seen in a plan view, two outer circumferential lines are seen. Therefore, it is possible to infer that the protrusions T have been formed on the side surfaces of the terminal parts 50.

Further, since through-holes are formed in the copper plate 10 by performing etching three times, it is possible to reduce protruberance of the side surface protrusions P of FIG. 10B as compared to the preliminary technology in which etching is performed twice.

Therefore, it becomes possible to reduce the arrangement pitch of the terminal parts 50, and it is possible to miniaturize the pattern of the terminal parts 50.

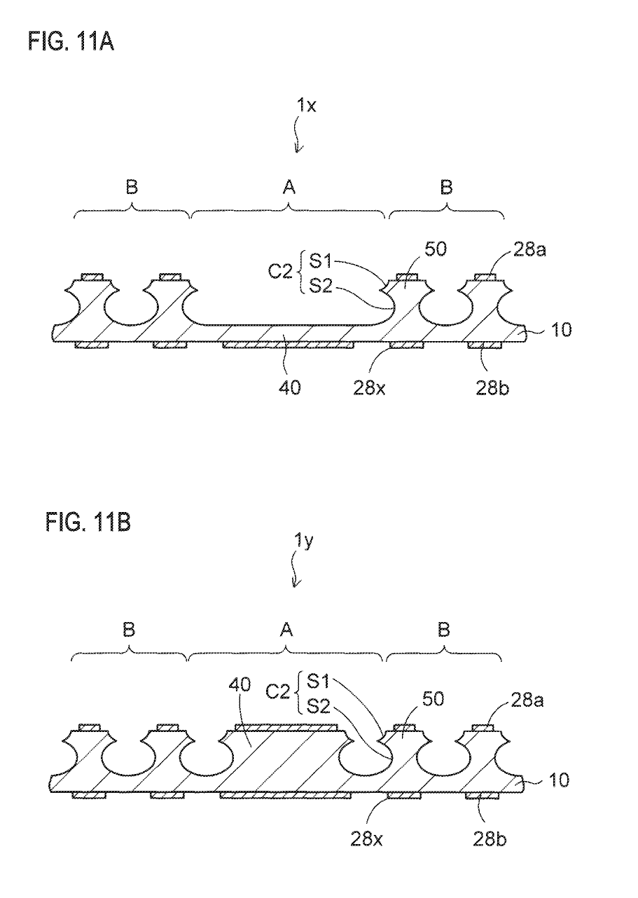

The structure of FIG. 7 described above may be used as a lead frame 1x as shown in FIG. 11A. In the lead frame 1x of the first embodiment, in a copper plate 10, a die pad part 40 of a die pad area “A” and terminal parts 50 of terminal areas “B” are connected.

In FIG. 11A, the die pad part 40 is disposed at the bottom surface of the second recess C2, and the terminal parts 50 are formed so as to protrude upward from one surface side of the planar copper plate 10.

Also, in another lead frame 1y of FIG. 11B, similarly, in a copper plate 10, a die pad part 40 of a die pad area “A” and terminal parts 50 of terminal areas “B” are connected. In FIG. 11B, all of the die pad part 40 and the terminal parts 50 are formed so as to protrude upward from one surface side of the copper plate 10 having a flat plate shape.

Also, in FIG. 11B, the die pad part 40 is formed so as to have a first side surface S1 and a second side surface S2, similarly to the terminal parts 50.

In a case of constructing an electronic component device using the lead frame 1y of FIG. 11B, as shown in FIG. 10A described above, the die pad part 40 is formed so as to have a first side surface S1, a second side surface S2, and a third side surface S3, similarly to the terminal parts 50, and the third side surfaces S3 of the die pad part 40 and the terminal parts 50 are exposed from the sealing resin 34.

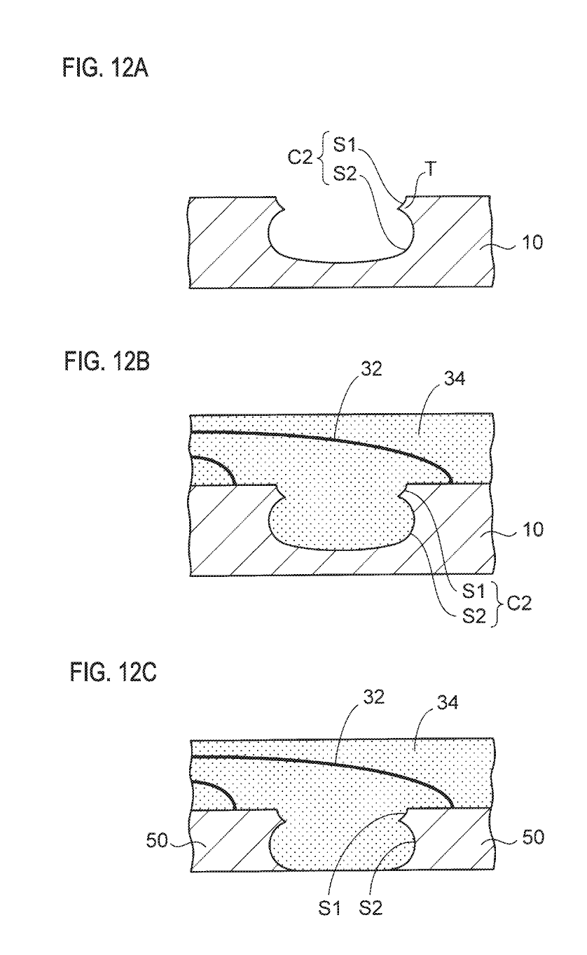

In FIGS. 12A to 12C, a method of manufacturing a lead frame of a modification of the first embodiment is shown. In the method of manufacturing the lead frame of the modification, first, similarly in FIG. 5B described above, second recesses C2 are formed in a copper plate 10 so as to have first and second side surfaces S1 and S2 as shown in FIG. 12A.

Next, a semiconductor chip 30 is mounted on a die pad area “A” of the copper plate 10, unlike in FIG. 8A described above in which a process of forming metal layers is performed, and the semiconductor chip 30 is connected to terminal areas “B” of the copper plate 10 by wires 32, as shown in FIG. 12B. Thereafter, the semiconductor chip 30, the wires 32, and the like are sealed with a sealing resin 34.

Subsequently, wet etching is performed on the entire bottom surface of the copper plate 10 such that the sealing resin 34 positioned at the bottoms of the second recesses C2 are exposed as shown in FIG. 12C. In this way, similarly in FIG. 10A described above, the die pad part 40 and the terminal parts 50 are separately formed.

Also, as another modification, in the process of FIG. 8A described above, the semiconductor chip may be flip-chip connected. In this case, although not particularly shown, in the process of FIG. 7 described above, the die pad area “A” of the copper plate 10 is formed as a terminal area “B”, and bump electrodes of the semiconductor chip are flip-chip connected to patterns to be terminal parts.

Subsequently, interstices under the semiconductor chip are filled with an underfill resin, and the semiconductor chip and the copper plate are sealed with a sealing resin, and etching is performed on the copper plate from the bottom surface, whereby individual terminal parts are obtained.

As described above, an electronic component is electrically connected to terminal parts of the lead frame by wire connection or flip-chip connection, whereby an electronic component device is constructed.

### Second Embodiment

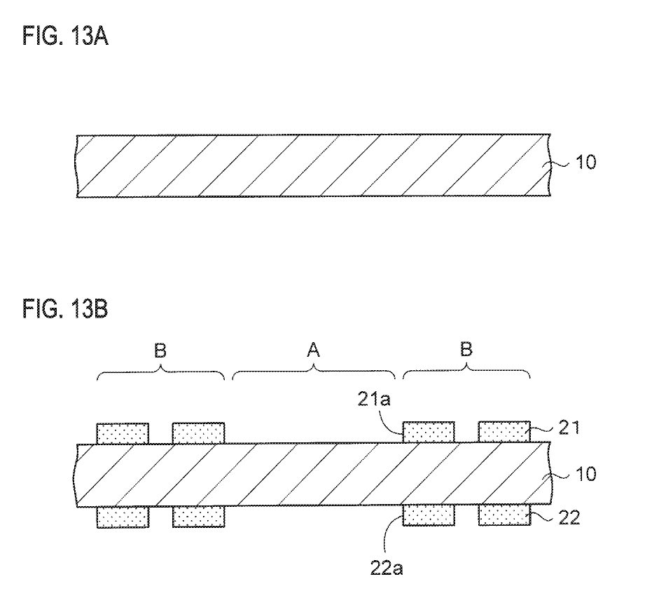

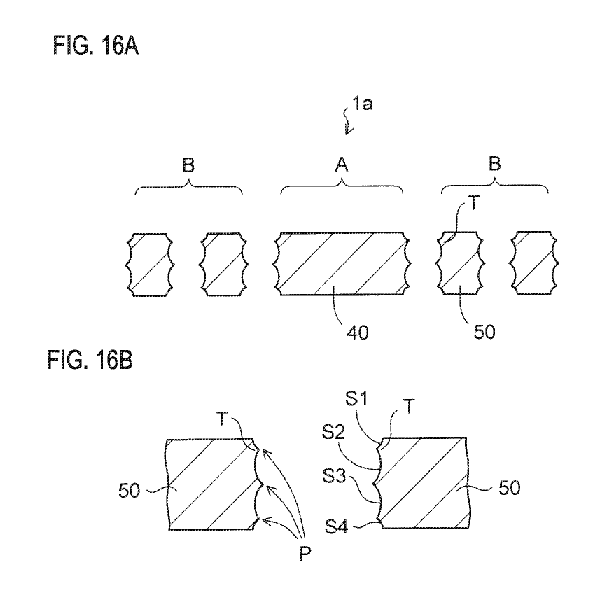

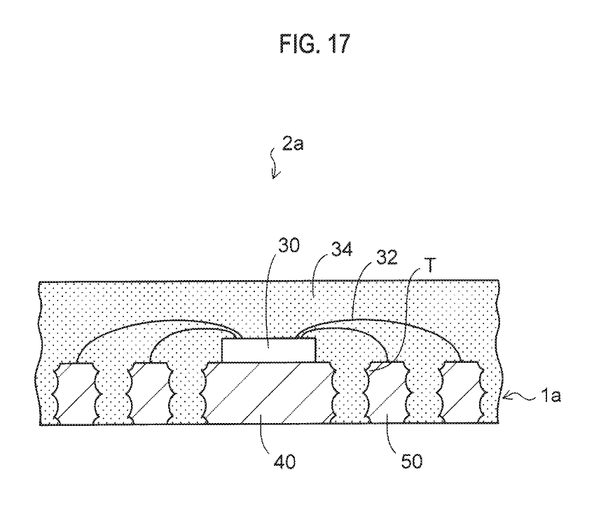

FIGS. 13A to 15B are views illustrating a method of manufacturing a lead frame of a second embodiment, and FIGS. 16A and 16B are views illustrating the lead frame of the second embodiment, and FIG. 17 is a view illustrating an electronic component device of the second embodiment.

In the above-described first embodiment, after etching is performed from the top surface of the copper plate twice, the third etching is performed from the bottom surface, whereby the terminal parts are formed such that each terminal part has three side surfaces, that is, first to third side surfaces connected in order.

The lead frame of the second embodiment is formed by performing first etching on the top surface and bottom surface of a copper plate at the same time, and forming second etching on the top surface and the bottom surface at the same time. Therefore, the side surface of each terminal part is formed so as to have four side surfaces, that is, first to fourth side surfaces having concave curve shapes and connected in order.

In the method of manufacturing the lead frame of the second embodiment, a copper plate 10 identical to that of FIG. 3A of the first embodiment is prepared as shown in FIG. 13A. Next, on the top surface of the copper plate 10, a first resist layer 21 is formed so as to have openings 21a as shown in FIG. 13B. Further, on the bottom surface of the copper plate 10, a second resist layer 22 is formed so as to have openings 22a at parts corresponding to the openings 21a of the first resist layer 21.

Similarly in the first embodiment, in the copper plate 10, there is a die pad area “A” defined for disposing a die pad part for mounting a semiconductor chip, and terminal areas “B” defined for disposing terminal parts.

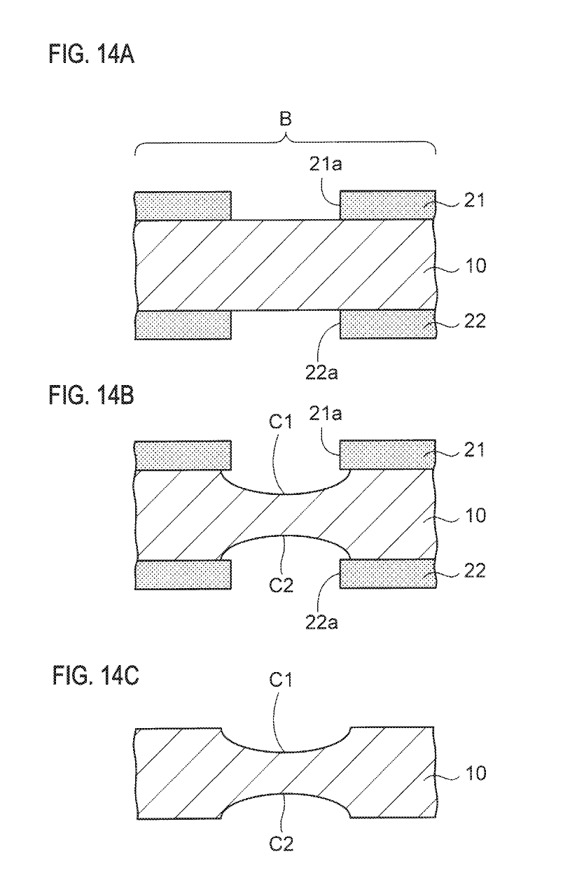

Similarly in the first embodiment, the following description will be made with reference to some drawings illustrating a part of terminal areas “B” of the copper plate 10 of FIG. 13B. FIG. 14A is an enlarged view of a part of the terminal areas “B” of the copper plate 10 of FIG. 13B.

Similarly in the process of FIG. 4B of the first embodiment, etching is performed on the copper plate 10 from the top surface through openings 21a of a first resist layer 21 formed on the top surface of the copper plate 10, whereby first recesses C1 are formed as shown in FIG. 14B.

Also, similarly, wet etching is performed from the bottom surface of the copper plate 100 through openings 22a of a second resist layer 22 formed on the bottom surface of the metal layer 10, whereby second recesses C2 are formed. Even in the second embodiment, in wet etching, an etching solution which does not contain any etching inhibitor is used.

Thereafter, the first resist layer 21 and the second resist layer 22 are removed as shown in FIG. 14C.

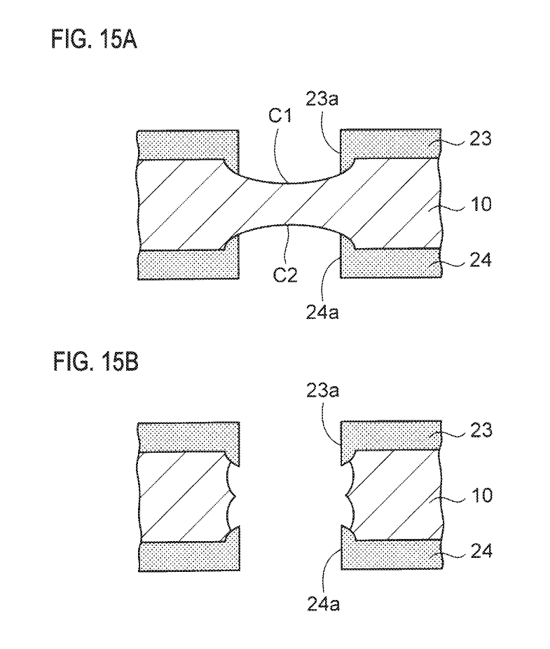

Next, similarly in the process of FIG. 4D of the first embodiment, a third resist layer 23 is formed on the top surface of the copper plate 10 of FIG. 14C so as to have openings 23a on the first recesses C1 as shown in FIG. 15A. Similarly in the first embodiment, the openings 23a of the third resist layer 23 are disposed on the central parts of the first recesses C1, with the circumferential edge parts of the inner wall surfaces of the first recesses C1 covered by the third resist layer 23.

Also, similarly, a fourth resist layer 24 is formed on the bottom surface of the copper plate 10 so as to have opening 24a on the second recesses C2. Similarly, the openings 24a of the fourth resist layer 24 are disposed on the central parts of the second recesses C2, with the circumferential edge parts of the inner wall surfaces of the second recesses C2 covered by the fourth resist layer 24.

Next, wet etching is performed on the copper plate 10 exposed from the bottoms of the first recesses C1, in the thickness direction, as shown in FIG. 15B, through the openings 23a of the third resist layer 23 formed on the top surface of the copper plate 10.

Also, at the same time, wet etching is performed on the copper plate 10 exposed from the bottoms of the second recesses C2, in the thickness direction, through the openings 24a of the fourth resist layer 24 formed on the bottom surface of the copper plate 10.

At this time, the etching surfaces from the top surface of the copper plate 10 and the etching surfaces from the bottom surface are connected, whereby through-holes are formed in the copper plate 10 between the top surface and the bottom surface in a pattern. Thereafter, the third resist layer 23 and the fourth resist layer 24 are removed.

In the above-described way, a lead frame 1a of the second embodiment is obtained as shown in FIGS. 16A and 16B.

FIG. 16A shows the shape of the entire lead frame 1a. The copper plate 10 of FIG. 13B described above is etched, whereby the lead frame 1a of FIG. 16 is obtained.

The lead frame 1a of the second embodiment has a die pad part 40, and terminal parts 50 disposed around the die pad part. The die pad part 40 and the terminal parts 50 are separated, thereby being electrically insulated. At this stage, the die pad part 40 and the terminal parts 50 have been connected by tie bars (not shown), and the terminal parts 50 have been connected by tie bars.

As shown in the partially enlarged sectional view of FIG. 16B, each terminal part 50 has a first side surface S1, a second side surface S2, a third side surface S3, and a fourth side surface S4 in order from the top. The first side surface S1 and the second side surface S2 are symmetrically disposed with the third side surface S3 and the fourth side surface S4 with respect to the boundary line of the second side surface S2 and the third side surface S3.

Similarly in FIGS. 10A and 10B of the first embodiment, the first side surfaces S1 are formed in a concave curve shape on the lower sides from the upper ends of the terminal parts 50. Also, similarly in FIGS. 10A and 10B of the first embodiment, the second side surfaces S2 are formed in a concave curve shape on the lower sides from the lower ends of the first side surfaces S1, such that the upper ends of the second side surfaces S2 border the lower ends of the first side surfaces S1.

The second side surfaces S2 are formed by etching the terminal parts 50 from the lower ends of the first side surfaces S1 so that the second side surfaces S2 have the shape having the depth in the horizontal direction. As a result, the boundary parts between the first side surfaces S1 and the second side surfaces S2 become protrusions T protruding outward.

Further, the third side surfaces S3 are formed in a concave curve shape on the lower sides from the lower ends of the second side surface S2, such that the upper ends of the third side surface S3 border the lower ends of the second side surfaces S2.

Also, the fourth side surfaces S4 are formed in a concave curve shape on the lower sides from the lower ends of the third side surface S3, such that the upper ends of the fourth side surface S3 border the lower ends of the third side surfaces S3. The lower ends of the fourth side surfaces S4 border the lower surfaces of the terminal parts 50.

In the second embodiment, since the side surface of each terminal part 50 has four side surfaces, that is, first to fourth side surfaces S1 to S4 having the concave curve shapes and connected in order, it has three side surface protrusions P at the boundaries of the first to fourth side surfaces.

Also, similarly to the terminal parts 50, the die pad part 40 has a first side surface S1, a second side surface S2, a third side surface S3, and a fourth side surface S4 in order from the top. Further, a surface of the die pad part 40 having the first side surfaces S1 disposed therein becomes an electronic-component mounting surface.

In the second embodiment, the first side surfaces S1 and the second side surfaces S2 of the terminal parts 50 are formed similarly in the terminal parts 50 of the first embodiment shown in FIGS. 10A and 10B, such that protrusions T are formed. Therefore, the lead frame 1a of the second embodiment achieves the same effects as those of the lead frame 1 of the first embodiment.

Also, in the second embodiment, since etching is performed on each of the top surface and bottom surface of the copper plate 10 twice, on the side surface of each terminal part 50, three side surface protrusions P are formed. As a result, the cross section shape becomes more complicated. Therefore, it is possible to further improve adhesion between the sealing resin 34 and the lead frame 1a.

Also, in the second embodiment, since the through-holes are formed in the copper plate 10 by practically performing etching four times, protruberance of the side surface protrusions P further decreases. Therefore, the second embodiment is advantageous in miniaturizing the terminal parts 50.

In the second embodiment, a semiconductor chip 30 is mounted on the electronic-component mounting surface of the die pad part 40 of the lead frame 1a as shown in FIG. 17. Further, connection parts of the semiconductor chip 30 are connected to the terminal parts 50 by wires 32.

Then, the semiconductor chip 30, the wires 32, and the lead frame 1a are sealed with a sealing resin 34. Thereafter, the tie bars (not shown) of the lead frame 1a are cut, whereby the die pad part 40 and the individual terminal parts 50 are separated from one another.

In the above-described way, an electronic component device 2a of the second embodiment is obtained.

Even in the second embodiment, a terminal part 50 may be formed in place of the die pad part 40 of the lead frame 1a. In this case, bump electrodes of the semiconductor chip 30 may be flip-chip connected to the corresponding terminal part 50.

### Third Embodiment

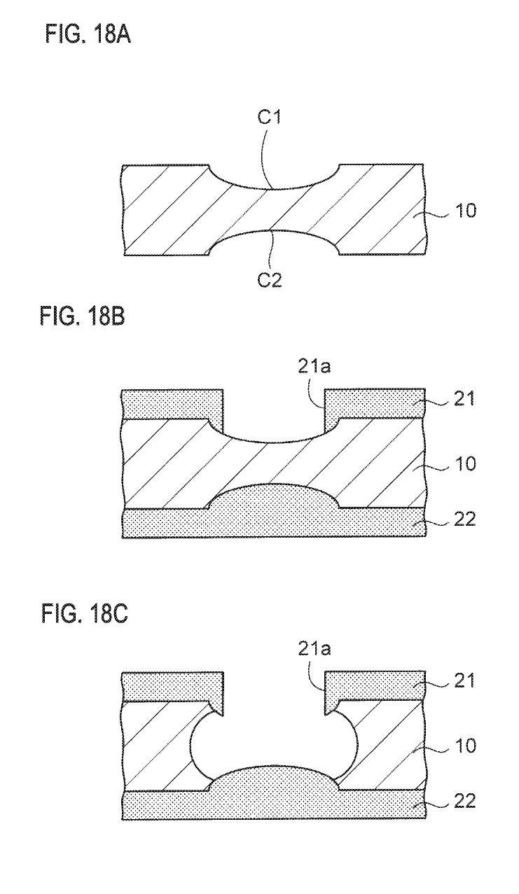

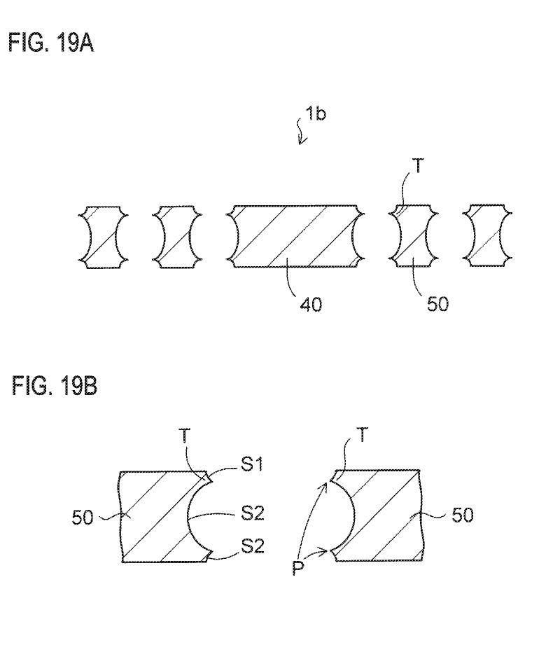

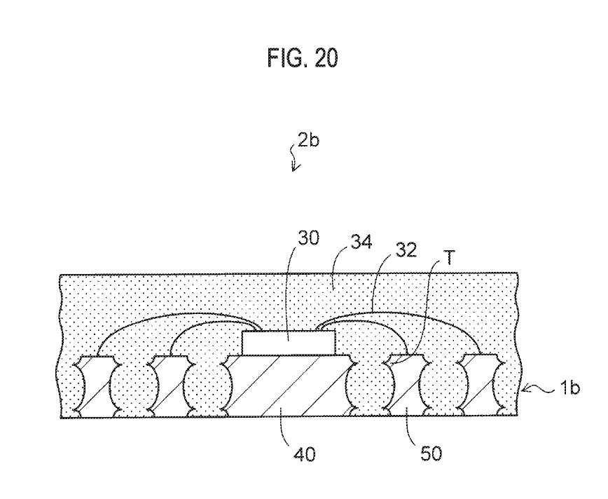

FIG. 18A to 18C are views illustrating a method of manufacturing a lead frame of a third embodiment, and FIGS. 19A and 19B are views illustrating the lead frame of the third embodiment, and FIG. 20 is a view illustrating an electronic component device of the third embodiment.

The lead frame of the third embodiment is formed by performing first etching on the top surface and bottom surface of the copper plate at the same time, and performing the second etching from the top surface. Therefore, the side surface of each terminal part is formed so as to have three side surfaces, that is, first to third side surfaces having concave curve shapes and connected in order.

In the method of manufacturing the lead frame of the third embodiment, first, as shown in FIG. 18A, a copper plate 10 having the same structure as that of FIG. 14C is prepared by the same method as that of FIGS. 14A and 14B of the second embodiment described above. In the top surface of the copper plate 10, first recesses C1 are formed, and in the bottom surface, second recesses C2 are formed.

Next, similarly in the process of FIG. 4D of the first embodiment, a first resist layer 21 is formed on the top surface of the copper plate 10 of FIG. 18A so as to have openings 21a on the first recesses C1 as shown in FIG. 18B.

Similarly in the first embodiment, the openings 21a of the first resist layer 21 are disposed on the central parts of the first recesses C1, with the circumferential edge parts of the inner wall surfaces of the first recesses C1 covered by the first resist layer 21.

Further, a second resist layer 22 is formed over the entire bottom surface of the copper plate 10 so as to protect the bottom surface having the second recesses C2.

Next, wet etching is performed on the copper plate 10 exposed from the bottoms of the first recesses C1, in the thickness direction, as shown in FIG. 18C, through the openings 21a of the first resist layer 21 formed on the top surface of the copper plate 10. At this time, etching is performed until the second resist layer 22 is exposed from the second recesses C2.

Even in the third embodiment, in wet etching, an etching solution which does not contain any etching inhibitor is used.

Thereafter, the first resist layer 21 and the second resist layer 22 are removed.

In the above-described way, a lead frame 1b of the third embodiment is obtained as shown in FIGS. 19A and 19B.

FIG. 19A shows the shape of the entire lead frame 1b. The copper plate 10 identical to that of FIG. 13B is etched, whereby the lead frame 1b of FIG. 19A is obtained.

As shown in FIG. 19A, the lead frame 1b of the third embodiment has a die pad part 40, and terminal parts 50 disposed around the die pad part. The die pad part 40 and the terminal parts 50 are separated, thereby being electrically insulated. At this stage, the die pad part 40 and the terminal parts 50 have been connected by tie bars (not shown), and the terminal parts 50 have been connected by tie bars.

As shown in the partially enlarged sectional view of FIG. 19B, each terminal part 50 has a first side surface S1, a second side surface S2, and a third side surface S3 in order from the top.

Similarly in FIGS. 10A and 10B of the first embodiment, the first side surfaces S1 are formed in a concave curve shape on the lower sides from the upper ends of the terminal parts 50.

Also, similarly in FIGS. 10A and 10B of the first embodiment, the second side surfaces S2 are formed in a concave curve shape on the lower sides from the lower ends of the first side surfaces S1, such that the upper ends of the second side surfaces S2 border the lower ends of the first side surfaces S1.

The second side surfaces S2 are formed by etching the terminal parts 50 from the lower ends of the first side surfaces S1 so that the second side surfaces S2 have the shape having the depth in the horizontal direction.

As a result, the boundary parts between the first side surfaces S1 and the second side surfaces S2 become protrusions T protruding outward.

Also, the third side surfaces S3 are formed in a concave curve shape from the lower ends of the second side surfaces S2 such that the upper ends of the third side surfaces S3 border the lower ends of the second side surfaces S2. The lower ends of the third side surfaces S3 border the lower surfaces of the terminal parts 50.

In the third embodiment, since the side surface of each terminal part 50 has three side surfaces, that is, first to third side surfaces S1 to S3 having the concave curve shapes and connected in order, it has two side surface protrusions P at the boundaries of the first to third side surfaces.

In the third embodiment, the first side surfaces S1 and the second side surfaces S2 of the terminal parts 50 are formed similarly in the terminal parts 50 of the first embodiment shown in FIGS. 10A and 10B, such that the protrusions T are formed. Therefore, the lead frame 1b of the third embodiment achieves the same effects as those of the lead frame 1 of the first embodiment.

Also, similarly to the terminal parts 50, the die pad part 40 has a first side surface S1, a second side surface S2, and a third side surface S3 in order from the top. Further, a surface of the die pad part 40 having the first side surface S1 disposed therein becomes an electronic-component mounting surface.

Next, similarly in FIG. 17 of the second embodiment, a semiconductor chip 30 is mounted on the electronic-component mounting surface of the die pad part 40 of the lead frame 1b as shown in FIG. 20. Then, connection parts of the semiconductor chip 30 are connected to the terminal parts 50 by wires 32.

Next, the semiconductor chip 30, the wires 32, and the lead frame 1b are sealed with a sealing resin 34. Thereafter, the tie bars (not shown) of the lead frame 1b are cut, whereby the die pad part 40 and the individual terminal parts 50 are separated from one another.

In the above-described way, an electronic component device 2b of the third embodiment is obtained.

Even in the third embodiment, a terminal part 50 may be formed in place of the die pad part 40 of the lead frame 1b. In this case, bump electrodes of the semiconductor chip 30 may be flip-chip connected to the corresponding terminal part 50.

### Fourth Embodiment

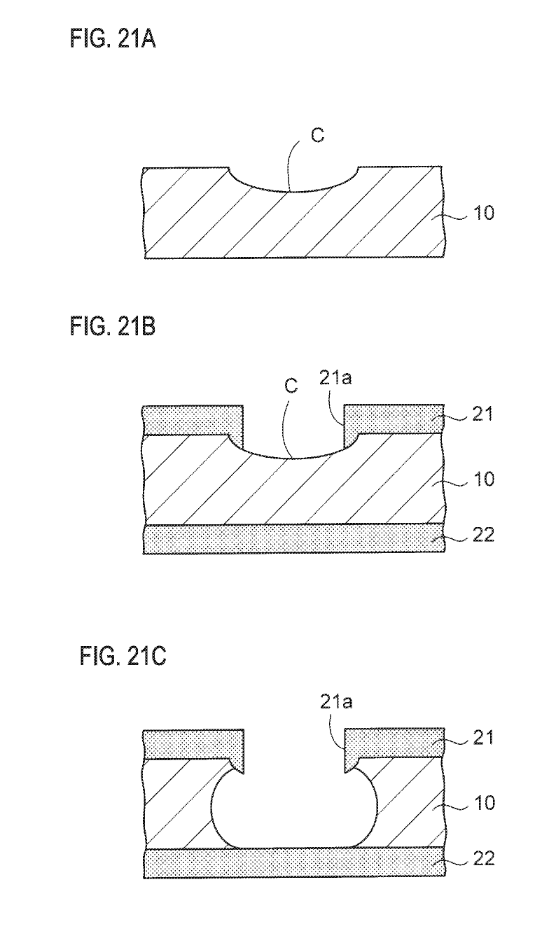

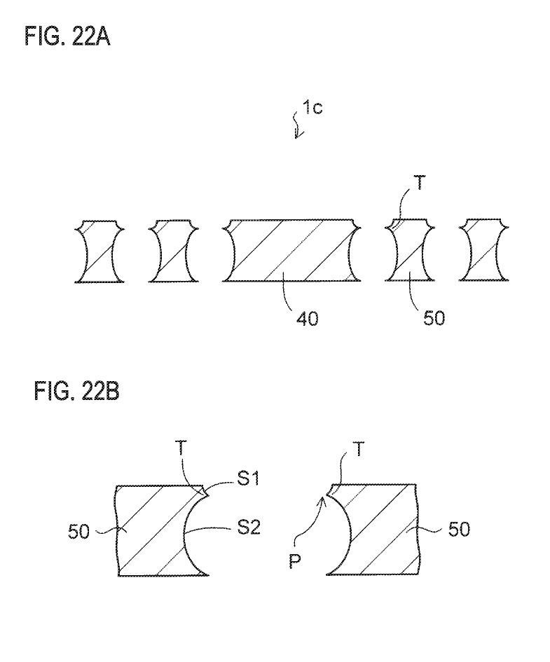

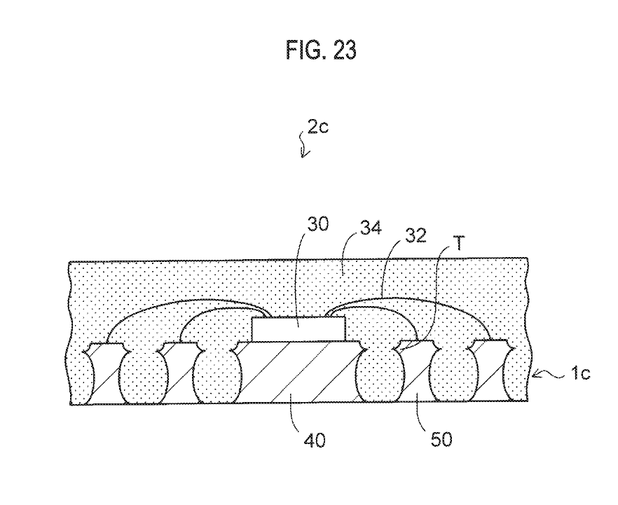

FIG. 21A to 21C are views illustrating a method of manufacturing a lead frame of a fourth embodiment, and FIGS. 22A and 22B are views illustrating the lead frame of the fourth embodiment, and FIG. 23 is a view illustrating an electronic component device of the fourth embodiment.

The lead frame of the fourth embodiment is formed by performing first etching on the top surface of a copper plate, thereby forming recesses, and forming second etching on the top surface. Therefore, the side surface of each terminal part is formed so as to have two side surfaces, that is, first and second side surfaces having concave curve shapes and connected.

As shown in FIG. 21A, a copper plate 10 identical to that of FIG. 4C is obtained by performing the processes of FIGS. 3A to 4C of the first embodiment described above. In the top surface of the copper plate 10, recesses C are formed.

Next, similarly in the process of FIG. 4D of the first embodiment, a first resist layer 21 is formed on the top surface of the copper plate 10 of FIG. 21A so as to have openings 21a on the recesses C as shown in FIG. 21B.

Similarly in the first embodiment, the openings 21a of the first resist layer 21 are disposed on the central parts of the recesses C, with the circumferential edge parts of the inner wall surfaces of the recesses C covered by the first resist layer 21. Also, a second resist layer 22 is formed over the entire bottom surface of the copper plate 10 so as to protect the bottom surface.

Next, wet etching is performed on the copper plate 10 exposed from the bottoms of the recesses C, in the thickness direction, as shown in FIG. 21C, through the openings 21a of the first resist layer 21 formed on the top surface of the copper plate 10.

At this time, etching is performed until the second resist layer 22 formed on the bottom surface of the copper plate 10 is exposed.

Even in the fourth embodiment, in wet etching, an etching solution which does not contain any etching inhibitor is used.

Thereafter, the first resist layer 21 and the second resist layer 22 are removed.

In the above-described way, a lead frame 1c of the fourth embodiment is obtained as shown in FIGS. 22A and 22B.

FIG. 22A shows the shape of the entire lead frame 1c. The copper plate 10 identical to that of FIG. 3B is etched, whereby the lead frame 1c of FIG. 22A is obtained.

As shown in FIG. 22A, the lead frame 1c of the fourth embodiment has a die pad part 40, and terminal parts 50 disposed around the die pad part. The die pad part 40 and the terminal parts 50 are separated, thereby being electrically insulated. At this stage, the die pad part 40 and the terminal parts 50 have been connected by tie bars (not shown), and the terminal parts 50 have been connected by tie bars.

As shown in the partially enlarged sectional view of FIG. 22B, each terminal part 50 has a first side surface S1 and a second side surface S2 in order from the top.

Similarly in FIGS. 10A and 10B of the first embodiment, the first side surfaces S1 are formed in a concave curve shape on the lower sides from the upper ends of the terminal parts 50.

Also, similarly in FIGS. 10A and 10B of the first embodiment, the second side surfaces S2 are formed in a concave curve shape on the lower sides from the lower ends of the first side surfaces S1, such that the upper ends of the second side surfaces S2 border the lower ends of the first side surfaces S1. The lower ends of the second side surfaces S2 border the lower surfaces of the terminal parts 50.

The second side surfaces S2 are formed by etching the terminal parts 50 from the lower ends of the first side surfaces S1 so that the second side surfaces S2 have the shape having the depth in the horizontal direction.

As a result, the boundary parts between the first side surfaces S1 and the second side surfaces S2 become protrusions T protruding outward.

In the fourth embodiment, since the side surface of each terminal part 50 has two side surfaces, that is, first and second side surfaces S1 and S2 having the concave curve shapes and connected, it has one side surface protrusion P at the boundary of the first and second side surfaces.

In the fourth embodiment, the first side surfaces S1 and the second side surfaces S2 of the terminal parts 50 are formed similarly in the terminal parts 50 of the first embodiment shown in FIGS. 10A and 10B, such that the protrusions T are formed. Therefore, the lead frame 1c of the fourth embodiment achieves the same effects as those of the lead frame 1 of the first embodiment.

Also, in the fourth embodiment, since etching is performed from the top surface of the copper plate 10 twice such that each terminal part 50 has one side surface protrusion P, it is possible to adjust the height position of the side surface protrusions P by the depth of the first etching.

Also, similarly to the terminal parts 50, the die pad part 40 has a first side surface S1 and a second side surface S2 in order from the top. Further, a surface of the die pad part 40 having the first side surface S1 disposed therein becomes an electronic-component mounting surface.

Further, similarly in FIG. 17, a semiconductor chip 30 is mounted on the electronic-component mounting surface of the die pad part 40 of the lead frame 1c as shown in FIG. 23. Next, connection parts of the semiconductor chip 30 are connected to the terminal parts 50 by wires 32. Then, the semiconductor chip 30, the wires 32, and the lead frame 1c are sealed with a sealing resin 34.

Thereafter, the tie bars (not shown) of the lead frame 1c are cut, whereby the die pad part 40 and the individual terminal parts 50 are separated from one another.

In the above-described way, an electronic component device 2c of the fourth embodiment is obtained.

Even in the fourth embodiment, a terminal part 50 may be formed in place of the die pad part 40 of the lead frame 1c. In this case, bump electrodes of the semiconductor chip 30 may be flip-chip connected to the corresponding terminal part 50.

### Fifth Embodiment

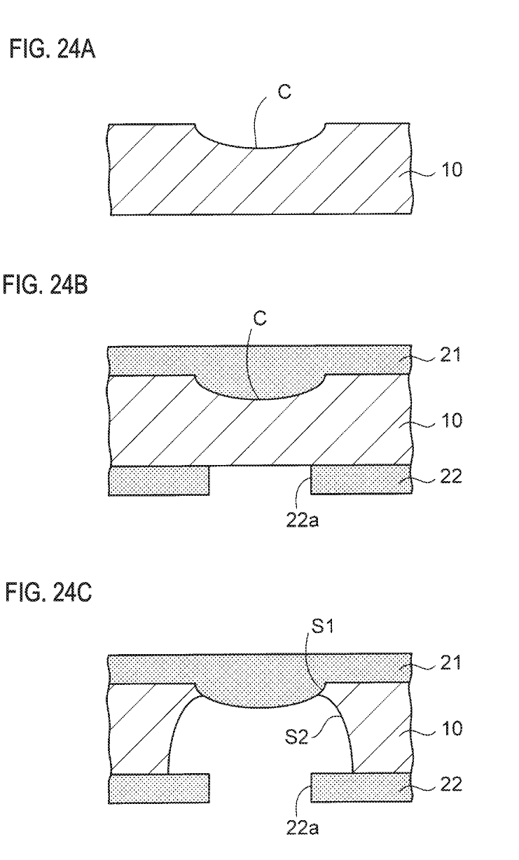

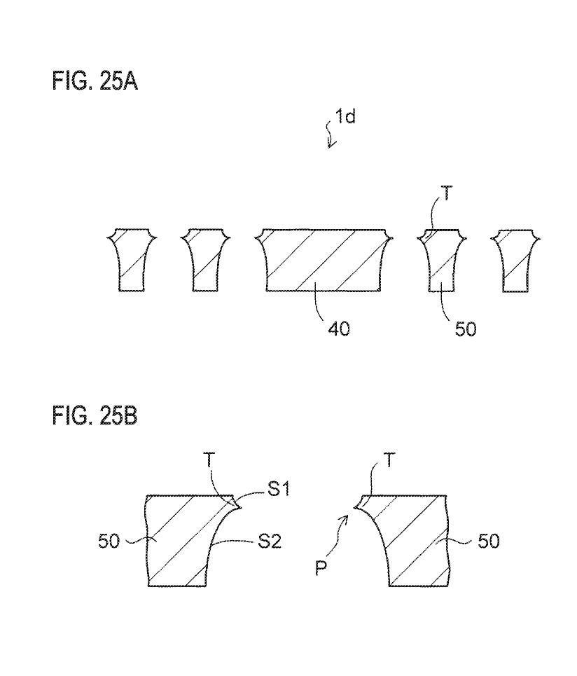

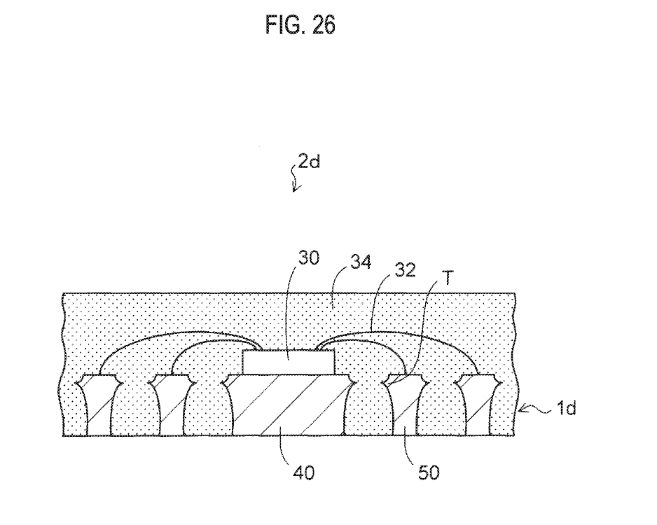

FIGS. 24A to 24C are views illustrating a method of manufacturing a lead frame of a fifth embodiment, and FIGS. 25A and 25B are views illustrating the lead frame of the fifth embodiment, and FIG. 26 is a view illustrating an electronic component device of the fifth embodiment.

The lead frame of the fifth embodiment is formed by forming recesses in the top surface of a copper plate by first etching and performing second etching from the bottom surface. Therefore, the side surface of each terminal part is formed so as to have two side surfaces, that is, first and second side surfaces having concave curve shapes and connected in order.

As shown in FIG. 24A, a copper plate 10 identical to that of FIG. 4C is obtained by performing the same processes as those of FIGS. 3A to 4C of the first embodiment described above. In the top surface of the copper plate 10, recesses C are formed.

Next, a first resist layer 21 is formed over the entire top surface of the copper plate 10 as shown in FIG. 24B so as to protect the top surface having the recesses C. Further, on the bottom surface of the copper plate 10, a second resist layer 22 is formed so as to have openings 22a at parts corresponding to the above-described recesses C.

Subsequently, wet etching is performed the copper plate 10 in the thickness direction on the bottom surface of as shown in FIG. 24C through the openings 22a of the second resist layer 22 formed on the bottom surface of the copper plate 10.

At this time, etching is performed until the first resist layer 21 is exposed from the recesses C of the copper plate 10. Therefore, on the upper end side of the copper plate 10, first side surfaces S1 composed of the circumferential edge parts of the inner wall surfaces of the recesses C are disposed, and the second side surface S2 formed by performing etching from the bottom surface of the copper plate 10 border the lower ends of the first side surfaces S1.

In this way, through-holes are formed in the copper plate 10 between the top surface and the bottom surface, in a pattern.

Even in the fifth embodiment, in wet etching, a wet etching solution which does not contain any etching inhibitor is used.

Thereafter, the first resist layer 21 and the second resist layer 22 are removed.

In the above-described way, a lead frame 1d of the fifth embodiment is obtained as shown in FIGS. 25A and 25B.

FIG. 25A shows the shape of the entire lead frame 1d. The copper plate 10 identical to that of FIG. 3B is etched, whereby the lead frame 1d of FIG. 25A is obtained.

As shown in FIG. 25A, the lead frame 1d of the fourth embodiment has a die pad part 40, and terminal parts 50 disposed around the die pad part. The die pad part 40 and the terminal parts 50 are separated, thereby being electrically insulated. At this stage, the die pad part 40 and the terminal parts 50 have been connected by tie bars (not shown), and the terminal parts 50 have been connected by tie bars.

As shown in the partially enlarged sectional view of FIG. 25B, each terminal part 50 has a first side surface S1 and a second side surface S2 in order from the top.

Similarly in FIGS. 10A and 10B of the first embodiment, the first side surfaces S1 are formed in a concave curve shape on the lower side from the upper ends of the terminal parts 50.

Also, the second side surfaces S2 are formed in a concave curve shape on the lower sides from the lower ends of the first side surfaces S1, such that the upper ends of the second side surfaces S2 border the lower ends of the first side surfaces S1. The lower ends of the second side surfaces S2 border the lower surfaces of the terminal parts 50.

The second side surfaces S2 are formed by etching the terminal parts 50 from the inner surfaces of the first side surfaces S1 so that the second side surfaces S2 have the shape having the depth in the horizontal direction. As a result, the boundary parts between the first side surfaces S1 and the second side surfaces S2 become protrusions T protruding outward.

In the fifth embodiment, since the side surface of each terminal part 50 has two side surfaces, that is, first and second side surfaces S1 and S2 having the concave curve shapes and connected, it has one side surface protrusion P at the boundary of the first and second side surfaces.

In the fourth embodiment, the first side surfaces S1 and the second side surfaces S2 of the terminal parts 50 are formed similarly in the terminal parts 50 of the first embodiment shown in FIGS. 10A and 10B, such that protrusions T are formed. Therefore, the lead frame 1d of the fourth embodiment achieves the same effects as those of the lead frame 1 of the first embodiment.

Also, in the fifth embodiment, since etching is performed from the top surface and bottom surface of the copper plate 10 several times such that each terminal part 50 has one side surface protrusion P, it is possible to adjust the height position of the side surface protrusions P by the depth of etching from the top surface.

Also, similar to the terminal parts 50, the die pad part 40 has a first side surface S1 and a second side surface S2 in order from the top. Further, a surface of the die pad part 40 having the first side surface S1 disposed therein becomes an electronic-component mounting surface.

Thereafter, similarly in FIG. 17, a semiconductor chip 30 is mounted on the electronic-component mounting surface of the die pad part 40 of the lead frame 1d as shown in FIG. 26. Then, connection parts of the semiconductor chip 30 are connected to the terminal parts 50 by wires 32.

Subsequently, the semiconductor chip 30, the wires 32, and the lead frame 1d are sealed with a sealing resin 34. Thereafter, the tie bars (not shown) of the lead frame 1b are cut, whereby the die pad part 40 and the individual terminal parts 50 are separated from one another.

In the above-described way, an electronic component device 2d of the fifth embodiment is obtained.

Even in the fifth embodiment, a terminal part 50 may be formed in place of the die pad part 40 of the lead frame 1d. In this case, bump electrodes of the semiconductor chip 30 may be flip-chip connected to the corresponding terminal part 50.

As described above in the first to fifth embodiments, in the embodiments, it is possible to manufacture lead frames having various cross section shapes according to designs by adjusting the number of times of etching which is performed on each of the top surface and bottom surface of the copper plate 100, and each etching depth.

This disclosure further encompasses various exemplary embodiments, for example, described below.

1. A method of manufacturing a lead frame, comprising:

a step of forming a first resist layer having an opening on an upper surface of a metal plate;

a first etching step of performing wet etching on the metal plate through the opening of the first resist layer to the middle of the thickness of the metal plate, thereby forming a first recess;

a step of removing the first resist layer;

a step of forming a second resist layer on the upper surface of the metal plate such that the second resist layer has an opening on the first recess while covering a circumferential edge part of an inner wall surface of the first recess; and

a second etching step of performing etching on the metal plate from a bottom surface of the first recess through the opening of the second resist layer,

wherein, by performing the second etching step,
a first side surface obtained from the circumferential edge part of the inner wall surface of the first recess and formed in a concave curve shape, the concave curve shape having a depth in a surface direction of the metal plate, and a second side surface bordering a lower end of the first side surface and formed in a concave curve shape, the concave curve shape having a depth in the surface direction of the metal plate, are formed,
a boundary part of the first side surface and the second side surface becomes a protrusion protruding outward, and
the depth of the concave curve shape of the second side surface is formed so as to be larger than the depth of the concave curve shape of the first side surface, and

a distance between an upper end and a lower end of the second side surface is set to be longer than a distance between an upper end and the lower end of the first side surface.

2. A method of manufacturing an electronic component device, comprising:

a step of forming a first resist layer having an opening on an upper surface of a metal plate;

a first etching step of performing wet etching on the metal plate through the opening of the first resist layer to the middle of the thickness of the metal plate, thereby forming a first recess;

a step of removing the first resist layer;

a step of forming a second resist layer on the upper surface of the metal plate such that the second resist layer has an opening on the first recess while covering a circumferential edge part of an inner wall surface of the first recess; and

a second etching step of performing etching on the metal plate from a bottom surface of the first recess through the opening of the second resist layer, and

a step of obtaining a lead frame having an area to be a die pad part and an area to be a terminal part formed by performing the second etching step;

a step of mounting an electronic component on the area to be the die pad part;

a step of sealing one surface side of the metal plate, the first side surface and the second side surface of the area to be the terminal part and the area to be the die pad part, and the electronic component, with a sealing resin; and

a step of performing etching on the metal plate from the other surface side, thereby obtaining the terminal part and the die pad part.

3. The method of manufacturing an electronic component device according to claim 2, wherein:

in the step of performing etching on the metal plate from the other surface side,
a third side surface is formed on a lower side from a lower end of the second side surface, and
the third side surface is formed so as to be exposed from the sealing resin and protrude downward from the sealing resin.

What is claimed is:

1. A lead frame comprising:
a terminal part formed of a metal plate; and
a die pad part formed of the metal plate,
wherein each of the terminal part and the die pad part comprises
a first side surface formed in a concave curve shape on a lower side from an upper end of the corresponding terminal part or the die pad part, the concave curve shape having a depth in a surface direction of the corresponding terminal part or the die pad part, and
a second side surface formed in a concave curve shape on a lower side from a lower end of the first side surface, the concave curve shape having a depth in the surface direction of the corresponding terminal part or the die pad part, and
wherein in said each of the terminal part and the die pad part,
a boundary part of the first side surface and the second side surface becomes a protrusion protruding outward,
the depth of the concave curve shape of the second side surface is larger than the depth of the concave curve shape of the first side surface,
a distance between an upper end and a lower end of the second side surface is longer than a distance between an upper end and a lower end of the first side surface, and
a surface of the die pad part positioned on a side where the first side surface is formed is an electronic-component mounting surface.

2. The lead frame according to claim 1, wherein:
said each of the terminal part and the die pad part has a third side surface formed in a concave curve shape on a lower side from the lower end of the second side surface, the concave curve shape having a depth in the surface direction of the corresponding terminal part or the die pad part.

3. The lead frame according to claim 2, wherein:
said each of the terminal part and the die pad part has a fourth side surface formed in a concave curve shape on a lower side from a lower end of the third side surface, the concave curve shape having a depth in the surface direction of the corresponding terminal part or the die pad part, and
the first side surface and the second side surface are symmetrically disposed with the third side surface and the fourth side surface with respect to a boundary line of the second side surface and the third side surface.

4. The lead frame according to claim 1, wherein:
the terminal part and the die pad part are formed so as to protrude from one surface of the metal plate having a flat plate shape.

5. A lead frame comprising:
a terminal part formed of a metal plate, wherein
the terminal part has
a first side surface formed in a concave curve shape on a lower side from an upper end of the terminal part, the concave curve shape having a depth in a surface direction of the terminal part, and
a second side surface formed in a concave curve shape on a lower side from a lower end of the first side surface, the concave curve shape having a depth in the surface direction of the terminal part,
a boundary part of the first side surface and the second side surface becomes a protrusion protruding outward,
the depth of the concave curve shape of the second side surface is larger than the depth of the concave curve shape of the first side surface, and
a distance between an upper end and a lower end of the second side surface is longer than a distance between an upper end and a lower end of the first side surface.

6. An electronic component device comprising:
a lead frame which includes
a terminal part formed of a metal plate, and
a die pad part formed of the metal plate, and
in which each of the terminal part and the die pad part has
a first side surface formed in a concave curve shape on a lower side from an upper end of the corresponding terminal part or the die pad part, the concave curve shape having a depth in a surface direction of the corresponding terminal part or the die pad part, and
a second side surface formed in a concave curve shape on a lower side from a lower end of the first side surface, the concave curve shape having a depth in the surface direction of the corresponding terminal part or the die pad part, and
in said each of the terminal part and the die pad part,
a boundary part of the first side surface and the second side surface becomes a protrusion protruding outward,
the depth of the concave curve shape of the second side surface is larger than the depth of the concave curve shape of the first side surface,
a distance between an upper end and a lower end of the second side surface is longer than a distance between an upper end and a lower end of the first side surface, and
a surface of the die pad part positioned on a side where the first side surface is formed is an electronic-component mounting surface;
an electronic component mounted on the electronic-component mounting surface of the lead frame and electrically connected to the terminal part; and
a sealing resin formed so as to cover the electronic component and the first side surfaces and the second side surfaces of the terminal part and the die pad part.

7. The electronic component device according to claim 6, wherein:
said each of the terminal part and the die pad part has a third side surface formed in a concave curve shape on a lower side from the lower end of the second side surface, the concave curve shape having a depth in the surface direction of the corresponding terminal part or the die pad part, and the third side surface is exposed from the sealing resin.
